(19) United States
(12) Patent Application Publication
(10) Pub. No.: US 2008/0310105 A1
(43) Pub. Date: Dec. 18, 2008

(54) HEAT DISSIPATING APPARATUS AND WATER COOLING SYSTEM HAVING THE SAME

(76) Inventor: Chia-Chun CHENG, Chung-Ho City (TW)

Correspondence Address: HDSL, P.O. BOX 220746, CHANTILLY, VA, 20153-0746, US

(21) Appl. No.: 11/762,843

(22) Filed: Jun. 14, 2007

(51) Int. Cl. H05K 7/20

(52) U.S. Cl. 361/695; 361/699

(57) ABSTRACT

A heat dissipating apparatus for a water cooling system includes a heat conducting base, a heat dissipating structure and a water block. The heat dissipating structure includes a heat pipe and a plurality of fins, the heat pipe has a first end and a second end, and the first end is connected to the heat conducting base for conducting heat and the second end is connected in series with each fin. The water block includes a hollow base and two connectors installed at two positions of the base and interconnected with the base, and the base is attached on a heated end of a heat pipe for conducting heat, and the two connectors are extended from the lateral directions.

### BACKGROUND OF THE INVENTION

1. Field of the Invention

The present invention relates to an air cooling system or a water cooling system, and more particularly to a heat dissipating apparatus applied in a computer motherboard for simultaneously dissipating the heat of each heat-generating electronic component on the motherboard, and a water cooling system having the heat dissipating apparatus.

2. Description of Prior Art

Since the technology and science related industry is developed rapidly and the functions of different heat-generating electronic components on a computer motherboard and its VGA card are enhanced, therefore a considerable amount of heat is produced in their operation. A heat sink or a heat dissipating apparatus corresponding to each of the aforementioned heat-generating electronic components is provided, and particularly, a central processing unit (CPU) generally adopts a water cooling circulation heat dissipating system to maintain a normal operation in an allowable temperature range.

In the past, a plurality of water blocks are installed on each heat-generating electronic component for the convenience of integration, and each water block is connected to a pipeline for the distribution of a coolant liquid and connected to a heat dissipating structure such as a pump and a plurality of fins to form a water cooling circulation system. The pump drives the coolant liquid to flow in each water block for a heat exchange, so as to achieve the heat dissipating effect of a plurality of heat-generating electronic components.

If a heat dissipation system for CPU is installed according to user's requirements in the DIY market and the CPU comes with a better performance, the corresponding heat sink or heat dissipating apparatus will have an increasingly higher demand on the heat dissipation performance. In addition to CPU, a computer motherboard also has other heat-generating electronic components such as Northbridge, Southbridge, MOSFET, and VGA chips. These heat-generating electronic components may bundle an air cooling heat sink or an air cooling heat dissipating apparatus. For single heat sources, the heat sources may be able to share the same set of water cooling heat dissipation system of the aforementioned heat-generating electronic components. For a plurality of heat sources, air cooling and water cooling systems cannot be integrated according to actual user requirements.

### SUMMARY OF THE INVENTION

In view of the foregoing shortcomings of the prior art, the inventor of the present invention based on years of experience in the related industry to conduct experiments and modifications, and finally developed a heat dissipating apparatus and a water cooling system having the heat dissipating apparatus in accordance with the present invention to overcome the shortcomings of the prior art.

Therefore, the present invention is to provide a heat dissipating apparatus and a water cooling system having the same, wherein the optional water cooling system purchased by a user is integrated with a heat dissipating apparatus corresponding to the actual required heat dissipating system of the CPU or a heat sink of other corresponding heat-generating electronic components on the motherboard. The invention not only solves the heat dissipation problem of each heat-generating electronic component on the computer motherboard, but also provides a standalone use to meet the requirements of the DIY market.

The present invention provides a heat dissipating apparatus, comprising a heat conducting base, a heat dissipating structure and a water block, and the heat dissipating structure includes a heat pipe and a plurality of fins. The heat pipe has a first end and a second end, and the first end is connected to the heat conducting base for conducting heat, and the second end is connected in series with each fin. The water block includes a hollow base, and two connectors disposed on and interconnected to two positions of the base are attached onto heated ends of the heat pipe for conducting heat. The two connectors are extended outward from the lateral directions, and connected with a water cooling system. Alternatively, the heat dissipating apparatus can be used as a standalone device without connecting in series with the water cooling system for the air cooling heat dissipation.

The present invention provides a water cooling system connected with the aforementioned heat dissipating apparatus and comprises a water cooling radiator, a water tank and a pump connected in parallel with each other by a plurality of pipelines to constitute a circulation loop.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is an exploded view of the present invention;

FIG. 2 is a perspective view of the present invention;

FIG. 3 is a section view of the present invention;

FIG. 4 is a perspective view of a water cooling system of the present invention; and

FIG. 5 is a section view of an application status of the present invention.

### DETAILED DESCRIPTION OF THE INVENTION

The technical characteristics, features and advantages of the present invention will become apparent in the following detailed description of the preferred embodiments with reference to the accompanying drawings. The drawings are provided for reference and illustration only, but not intended for limiting the present invention.

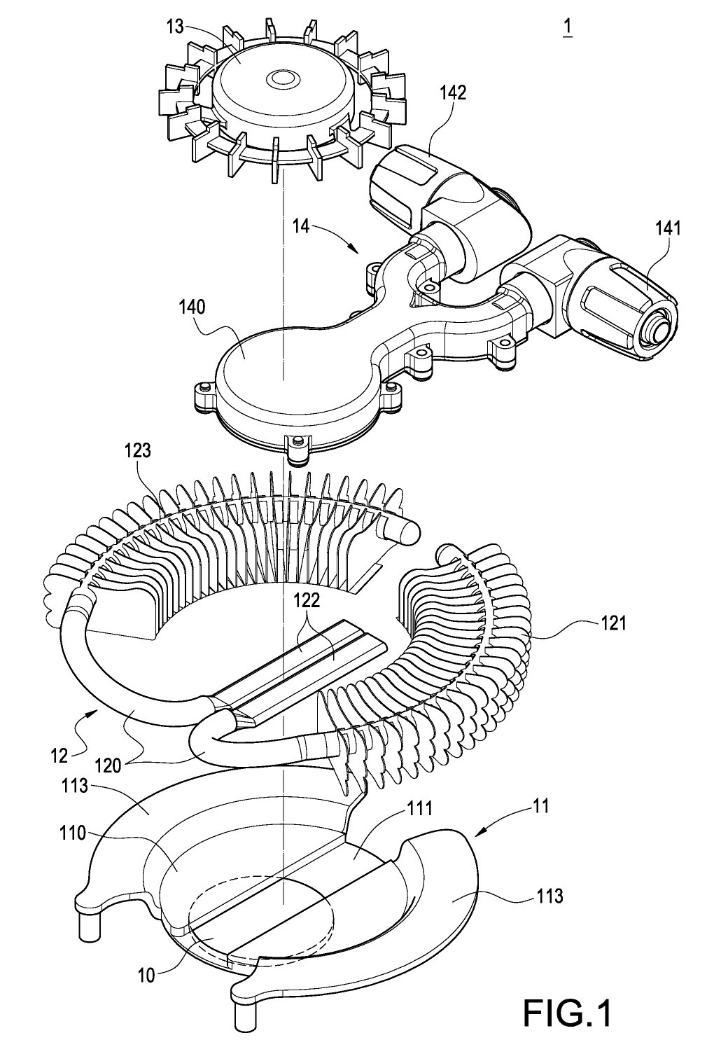

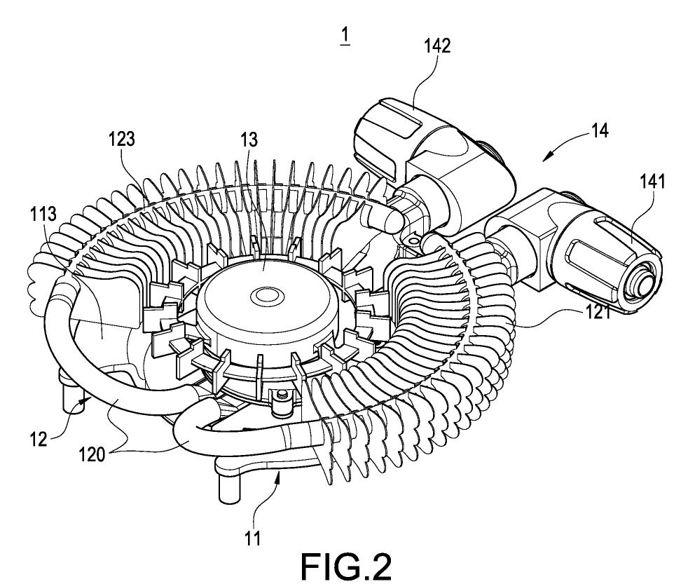

Referring to FIGS. 1 and 2 for an exploded view and a perspective view of the present invention respectively, the invention provides a heat dissipating apparatus and a water cooling system having the same, and the heat dissipating apparatus 1 comprises a heat conducting base 10, a heat dissipating structure 12, a fan 13 and a water block 14.

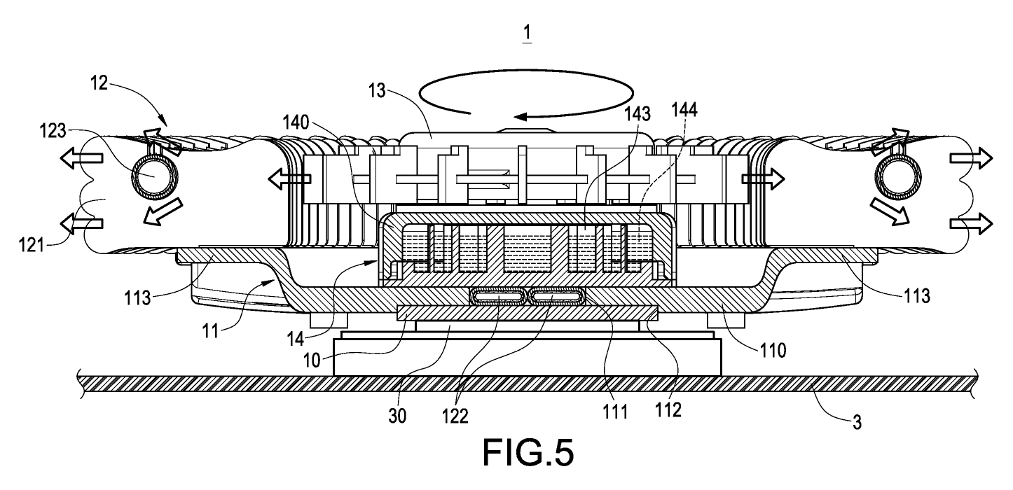

The heat conducting base 10 is made of a material with a good thermal conductivity such as copper or aluminum, and attached onto a heat-generating electronic component 30 (as shown in FIG. 5) for absorbing the heat produced by the heat-generating electronic component 30.

The heat dissipating structure 12 is connected to the aforementioned heat conducting base 10 for conducting the heat of the heat-generating electronic component 30 absorbed by the heat conducting base 10 to the heat dissipating structure 12 for dissipating the heat. In this embodiment of the invention, the heat dissipating structure 12 includes a heat pipe 12 and a plurality of fins 121 connected in series with the heat pipe 120, wherein the heat pipe 120 has a first end 122 and a second end 123, and the first end 122 is provided for receiving heat and it can be in a flat shape and connected to the heat conducting base 10 for conducting heat to heat up the flat bottom, and the second end 123 is provided for cooling and condensation and can be connected in series with each fin. In this embodiment, the first ends 122 of the two heat pipes 120 are arranged in parallel with each other, so that the second ends 123 are situated horizontally in both lateral directions to constitute a circular arrangement, and the fins 121 can be arranged along the second end 123 with an interval apart from each other into a sector shape.

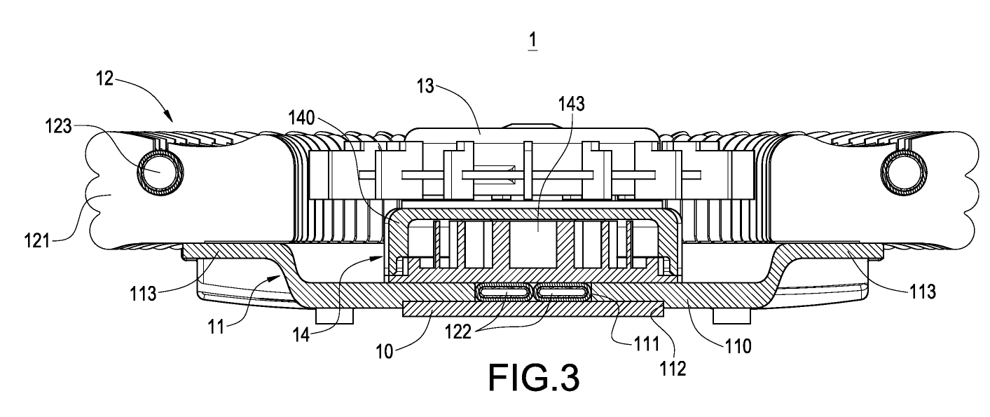

To retain the aforementioned heat dissipating structure 12, a tray 11 is installed between the heat conducting base 10 and the heat dissipating structure 12. Referring to FIG. 3 as well, the tray 11 has a bottom 110, and the lower section of the bottom 110 is attached to the heat conducting base 10 and sunk into an embedding groove 112 disposed at the lower section of the bottom 110 and provided for the heat conducting base 10 to be embedded into the embedding groove 112, and the top of the tray 11 is recessed for subsiding the first end 122 of the heat pipe 120 into a ditch 111 and penetrated at a position of the ditch 111 corresponding to the heat conducting base 10, such that the first end 122 of heat pipe 120 can be connected to the heat conducting base 10 for conducting heat. The tray 11 has a circular support portion 113 extended outward from the periphery of the bottom 110, and the circular support portion 113 supports each fin 121 at the bottom of each fin 121, so as to retain the heat dissipating structure 12 on the heat conducting base 10.

The fan 13 can be a centrifugal fan installed at the center of a sector arrangement of the fins 121 for assisting the heat dissipating structure 12 to dissipate heat by an air cooling method, and the actual situation of the required heat dissipation effect determines whether or not it is necessary to install the fan 13.

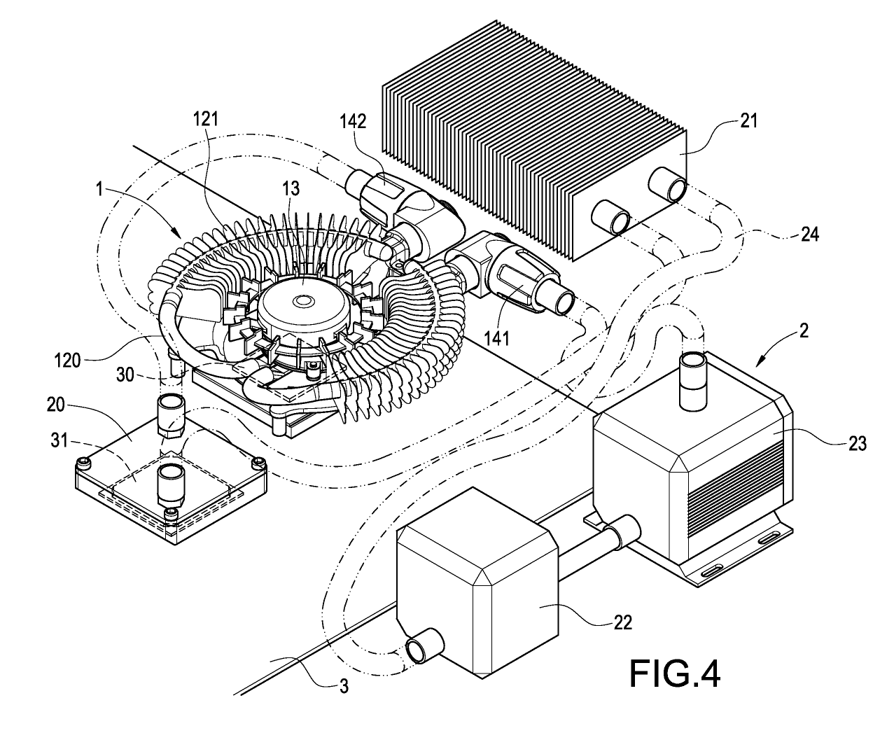

The water block 14 is provided for users to connect the heat dissipating apparatus 1 in series with a water cooling system 2 (as shown in FIG. 4) and facilitate a parallel connection with the water cooling system 2 for simultaneously dissipating the heat produced by each heat-generating electronic component 30, 31 on the computer motherboard 3 as well as each chip on the display card. In FIG. 3, the water block 14 includes a base 140 containing a chamber 143 therein and two connectors 141, 142 installed at two positions of the base 140, and the two connectors 141, 142 are interconnected with the base 140 and provided for connecting a pipeline 24 of the water cooling system 2 (as shown in FIG. 4) to form a circulation loop, and the base 140 is attached onto the first end 122 of the heat pipe 120 for conducting heat and retained by the tray 11. The two connectors 141, 142 are extended outward from the lateral directions, so that the absorbed heat can be transmitted from the first end 122 of the heat pipe 120 to the base 140 of the water block 14, and the heat of the externally connected water cooling system 2 can be carried away, and the aforementioned fan 13 corresponds to the top of the base 140.

If the water cooling system 2 is not connected in series as shown in FIG. 3, the heat dissipating apparatus 1 can still maximize its utility by using the heat conducting base 10 to absorb the heat produced by the heat-generating electronic components 30, and conducting the heat to the first end 122 of heat pipe 120, and then the heat pipe 120 transmits the heat to each fin 121. By the cool air flow produced by the fan 13, the heat of the corresponding heat-generating electronic components 30 can be dissipated by the air cooling method.

Referring to FIGS. 4 and 5, if it is necessary to adopt the water cooling method as well, the two connectors 141, 142 of the water block 14 are connected in series with the pipeline 24 of the water cooling system 2, and the water cooling system 2 uses its water block 20 to assist another heat-generating electronic component 31 to dissipate the heat. Since components including the water cooling radiator 21, the water tank 22 and the pump 23 are connected in series by the pipeline 24, therefore the heat of each heat-generating electronic component 30, 31 on the motherboard 3 can be dissipated after the pipeline connected in series with the water block 14 forms a circulation loop. In addition to the air cooling effect, the water block 14 also absorbs the heat at the first end 122 of the heat pipe 120, and the flat top of the first end 122 can be cooled by condensation, and a coolant liquid 144 in a chamber 143 can carry away the heat, so as to meet the requirement of dissipating heat by both water cooling and air cooling methods and provide an effect better than the air cooling method only.

It is worthy to point out that the heat dissipating apparatus 1 for dissipating heat by the air cooling method only is integrated with the water cooling system 2, and then both apparatus 1 and system 2 can provide the heat dissipation effect for the heat-generating electronic components 30, such that if any one of the two fails or breaks down, the other can still provide the heat dissipation effect for the heat-generating electronic components 30 and maintain a normal operation. The invention can prevent damages or adverse effects if a heat-generating electronic components 30 loses one of its heat dissipating functions.

The present invention is illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A heat dissipating apparatus, comprising:
a heat conducting base,
a heat dissipating structure, including a heat pipe and a plurality of fins, the heat pipe including a first end and a second end, and the first end being connected to the heat conducting base for conducting heat and the second end being connected in series with each of the fins; and
a water block, including a hollow base and two connectors disposed on two positions of the base and interconnected with the base, the base being attached on a heated end of the heat pipe for conducting heat, and the two connectors being extended from both lateral directions;
thereby, the two connectors of the water block are used for connecting a water cooling system in series.

2. The heat dissipating apparatus as recited in claim 1, wherein the first end of the heat pipe is substantially in a flat shape and attached between the heat conducting base and the base of the water block.

3. The heat dissipating apparatus as recited in claim 1, wherein the heat pipe comes with a quantity of two, and the first ends of the two heat pipes are arranged in parallel with each other, and the second ends of the two heat pipes are disposed horizontally in two lateral directions to constitute a circular arrangement, such that the fins are arranged along the second ends with an interval apart and into a sector shape.

4. The heat dissipating apparatus as recited in claim 3, further comprising a fan disposed at a top of the base of the water block.

5. The air cooling heat dissipating apparatus connected in series with a water cooling system as recited in claim 4, wherein the fan is installed at a central position of a sector arrangement of the fins.

6. The heat dissipating apparatus as recited in claim 4, wherein the fan is a centrifugal fan.

7. The heat dissipating apparatus as recited in claim 1, further comprising a fan, and the fan is installed at a top of the base of the water block.

8. The heat dissipating apparatus as recited in claim 7, wherein the fan is a centrifugal fan.

9. The heat dissipating apparatus as recited in claim 1, further comprising a tray, and the tray has a bottom, and a lower portion of the bottom is attached with the heat conducting base for supporting the base of the water block.

10. The heat dissipating apparatus as recited in claim 9, wherein a top of the tray is recessed for sinking the heated end of the heat pipe into a ditch, and penetrating the heated end into the ditch at a corresponding position of the heat conducting base to connect the heated end of the heat pipe with the heat conducting base for conducting heat.

11. The heat dissipating apparatus as recited in claim 9, wherein a lower section of the bottom of the tray is sunk into an embedding groove, and the heat conducting base is embedded into the embedding groove.

12. The heat dissipating apparatus as recited in claim 9, wherein the tray has a circular support portion extended outward from a periphery of a bottom thereof for supporting bottoms of corresponding fins of the heat dissipating structure.

13. A water cooling system, connected in parallel with a heat dissipating apparatus comprising:
a heat conducting base,
a heat dissipating structure, including a heat pipe and a plurality of fins, the heat pipe including a first end and a second end, and the first end being connected to the heat conducting base for conducting heat and the second end being connected in series with each of the fins; and
a water block, including a hollow base and two connectors disposed on two positions of the base and interconnected with the base, the base being attached on a heated end of the heat pipe for conducting heat, and the two connectors being extended from both lateral directions;
thereby, the two connectors of the water block are used for connecting a water cooling system in series,
the water cooling system comprising a water cooling radiator, a water tank and a pump connected in series by a plurality of pipelines, and the pipelines being connected in series with the heat dissipating apparatus to constitute a circulation loop.
